(19) United States
(12) Patent Application Publication
(10) Pub. No.: US 2025/0298318 A1
(43) Pub. Date: Sep. 25, 2025

(54) LOCALIZED COATING OF FUNCTIONAL FILM

(71) Applicant: Applied Materials, Inc., Santa Clara, CA (US)

(72) Inventors: Jinyu LU, Santa Clara, CA (US); Rami HOURANI, Santa Clara, CA (US); Chia-Wei HUANG, Sunnyvale, CA (US); Zefang WANG, Santa Clara, CA (US); Lei JIANG, San Ramon, CA (US); Sri Vidya VENKATESH, San Jose, CA (US); Yingdong LUO, Newark, CA (US); Xiaopei DENG, San Jose, CA (US); Ludovic GODET, Sunnyvale, CA (US)

(21) Appl. No.: 19/081,005

(22) Filed: Mar. 17, 2025

Related U.S. Application Data
(60) Provisional application No. 63/568,702, filed on Mar. 22, 2024.

(51) Int. Cl. G03F 7/16; B08B 3/08; B41M 7/00; G03F 7/00

(52) U.S. Cl. CPC G03F 7/168; B08B 3/08; B41M 7/0081; G03F 7/0007

(57) ABSTRACT

Embodiments of the present disclosure generally relate methods of forming films for optical devices. A method of forming a film on an optical device includes disposing a film on a patterned substrate, directing ultraviolet (UV) light toward the patterned substrate to form a first portion of the film and a second portion of the film, and removing one of the first portion of the film or the second portion of the film. The patterned substrate includes a first grating and a second grating, the first grating and second grating formed from optical device structures. The film is disposed on at least one of the first grating or second grating.

### CROSS-REFERENCE TO RELATED APPLICATIONS

This application claims priority to U.S. provisional Patent Application Ser. No. 63/568,702, filed Mar. 22, 2024, which is incorporated herein by reference.

### BACKGROUND

### Field

Embodiments of the present disclosure generally relate to optical devices for augmented, virtual, and mixed reality. More specifically, embodiments described herein provide for methods of forming films for optical devices.

### Description of the Related Art

Virtual reality is generally considered to be a computer generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment.

Augmented reality, however, enables an experience in which a user can still see through the display lenses of the glasses or other HMD device to view the surrounding environment, yet also see images of virtual objects that are generated for display and appear as part of the environment. Augmented reality can include any type of input, such as audio and haptic inputs, as well as virtual images, graphics, and video that enhances or augments the environment that the user experiences. As an emerging technology, there are many challenges and design constraints with augmented reality.

One such challenge is area selective depositions on optical devices. The edges of deposited coatings are usually not uniform. Accordingly, what is needed in the art are improved methods of forming films.

### SUMMARY

Embodiments of the present disclosure generally relate methods of forming films for optical devices. A method of forming a film on an optical device includes disposing a film on a patterned substrate, directing ultraviolet (UV) light toward the patterned substrate to form a first portion of the film and a second portion of the film, and removing one of the first portion of the film or the second portion of the film.

In another embodiment a method is provided. The method includes disposing an inkjet film on a patterned substrate by inkjet deposition, and curing the inkjet film with ultraviolet (UV) light to form a cured film, wherein at least part of the inkjet film is disposed over a grating of the optical device.

In another embodiment a method is provided. The method includes disposing a film on a patterned substrate by a chemical vapor deposition (CVD), disposing a photoresist on the film, curing a portion of the photoresist disposed on the film to form a cured portion of the photoresist and an uncured portion of the photoresist, performing one or more etch operations, and applying oxygen to the film.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a perspective, frontal view of a substrate according to embodiments described herein.

FIG. 1B is a perspective, frontal view of an optical device according to embodiments described herein.

FIG. 2 is a schematic, cross-sectional view of an apparatus for inkjet deposition according to embodiments described herein.

FIG. 3 is a schematic, cross-sectional view of an exemplary processing chamber, according to certain embodiments of the present disclosure.

FIG. 4 illustrates a flow diagram of exemplary operations included in a film formation method, according to certain embodiments of the present disclosure.

FIGS. 5A-5E are schematic, cross-sectional views of an optical device during a method of forming a film according to some embodiments.

FIG. 6 illustrates a flow diagram of exemplary operations included in a film formation method, according to certain embodiments of the present disclosure.

FIGS. 7A-7G are schematic, cross-sectional views of an optical device during a method of forming a film according to some embodiments.

FIG. 8 illustrates a flow diagram of exemplary operations included in a film formation method, according to certain embodiments of the present disclosure.

FIGS. 9A-9G are schematic, cross-sectional views of an optical device during a method of forming a film according to some embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to optical devices for displays, augmented, virtual, and mixed reality. More specifically, embodiments described herein provide for film forming methods and systems. A film deposition system is also shown and described herein.

The method of forming a film includes depositing a film over gratings of an optical device. In some embodiments, the film is deposited by an inkjet deposition with a subsequent strip process to remove the non-uniform edge or the deposited film and form the patterned film. In some embodiments, the film is deposited by vapor deposition with a subsequent photolithography operation and etch to form the patterned film.

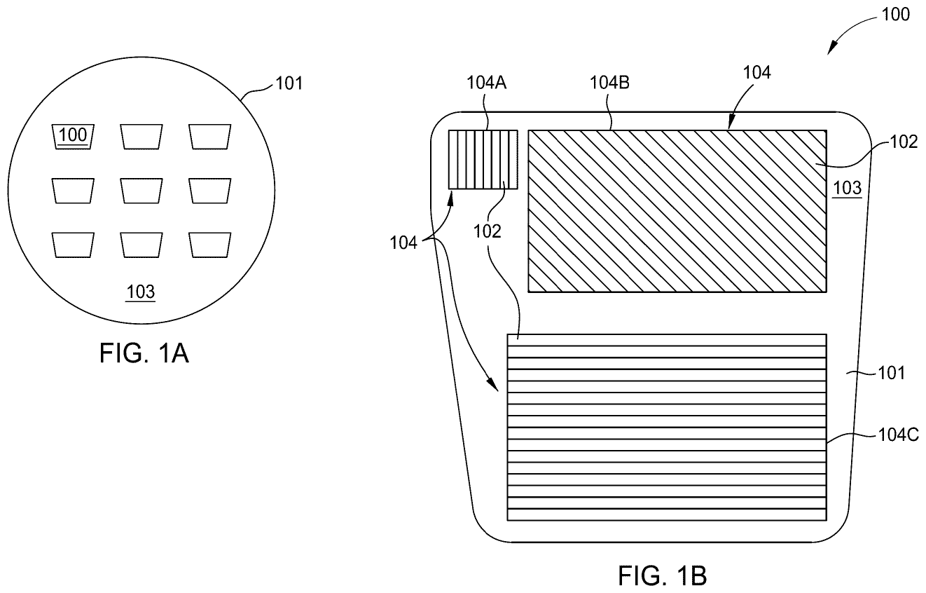

FIG. 1A is a perspective, frontal view of a substrate 101 according to embodiments described herein. The substrate includes a plurality of optical devices 100 disposed on a surface 103 of the substrate 101. In some embodiments, which can be combined with other embodiments described herein, the optical devices 100 are waveguide combiners utilized for virtual, augmented, or mixed reality. In some embodiments, which can be combined with other embodiments described herein, the optical devices 100 are flat optical devices, such as metasurfaces.

The substrate 101 can be any substrate used in the art, and can be either opaque or transparent to a chosen laser wavelength depending on the use of the substrate 101. The substrate 101 includes, but is not limited to, silicon (Si), silicon dioxide (SiO₂), fused silica, quartz, silicon carbide (SiC), germanium (Ge), silicon germanium (SiGe), indium phosphide (InP), gallium arsenide (GaAs), gallium nitride (GaN), silicon nitride (SiN), or sapphire containing materials. Additionally, the substrate 101 may have varying shapes, thicknesses, and diameters. For example, the substrate 101 may have a diameter of about 150 mm to about 300 mm. The substrate 101 may have a circular, rectangular, or square shape. The substrate 101 may have a thickness of between about 300 μm to about 1 mm. Any number of optical devices 100 may be disposed on the surface 103 of the substrate 101.

FIG. 1B is a perspective, frontal view of an optical device 100. It is to be understood that the optical devices 100 described herein are exemplary optical devices and the other optical devices may be used with or modified to accomplish aspects of the present disclosure. The optical device 100 may be a waveguide with a plurality of optical device structures 102 disposed on a surface 103 of a substrate 101. The optical device structures 102 may be nanostructures having sub-micron dimensions, e.g., nano-sized dimensions. In some embodiments, which may be combined with other embodiments, the plurality of optical device structures 102 include titanium. For example, the optical device structures 102 are titanium dioxide structures. In some embodiments, which may be combined with other embodiments, the plurality of optical device structures 102 have a refractive index between 1.3 and 2. For example, the optical device structures 102 have a refractive index of about 1.45. In yet another example, the optical device structures 102 have a refractive index of about 1.7. Regions of the optical device structures 102 correspond to one or more gratings 104, such as a first grating 104a, a second grating 104b, and a third grating 104c. In one embodiment, which can be combined with other embodiments, the first grating 104a, the second grating 104b and the third grating 104c, are formed from the optical device structures 102. In one embodiment, which can be combined with other embodiments described herein, the optical device 100 includes at least the first grating 104a corresponding to an input coupling grating, the second grating 104b corresponding to an expanding pupil grating and the third grating 104c corresponding to an output coupling grating. In another embodiment, which can be combined with other embodiments described herein, the optical device 100 also includes the second grating 104b corresponding to an intermediate grating. The optical device structures 102 may be angled or binary. The optical device structures 102 may have other cross-sections including, but not limited to, circular, triangular, elliptical, regular polygonal, irregular polygonal, and/or irregular shaped cross-sections.

In embodiments where the optical device 100 is a waveguide combiner, the optical device 100 can include the first grating 104a defined by a plurality grating structures 102, the second grating 104b defined by a plurality of grating structures 102, and the third grating 104c defined by a plurality of grating structures 102. In such embodiments, the first grating 104a receives incident beams of light (e.g., a virtual image) having an intensity from a microdisplay. Each grating structure of the plurality of grating structures 102 of the first grating 104a splits the incident beams into a plurality of modes, each beam having a mode. Zero-order mode (T0) beams are refracted back or lost in the optical device 100, positive first-order mode (T1) beams are coupled though the optical device 100 to the second grating 104b, and negative first-order mode (T-1) beams propagate in the optical device 100 a direction opposite to the T1 beams. The T1 beams undergo total-internal-reflection (TIR) through the optical device 100 until the T1 beams come in contact with the plurality of grating structures 102 in the second grating 104b. A portion of the first grating 104a may have grating structures 102 with a slant angle different than the slant angle of grating structures 102 from an adjacent portion of the first grating 104a.

The T1 beams that undergo TIR in the second grating 104b continue to contact grating structures of the plurality of grating structures 102 until the either the intensity of the T1 beams coupled through the optical device 100 to the second grating 104b is depleted, or remaining T1 beams propagating through the second grating 104b reach the end of the second grating 104b. The plurality of grating structures 102 must be tuned to control the T1 beams coupled through the optical device 100 to the second grating 104b in order to control the intensity of the T-1 beams coupled to the third grating 104c to modulate a field of view of the virtual image produced from the microdisplay from a user's perspective. A portion of the second grating 104b may have grating structures 102 with a slant angle different than the slant angle of grating structures 102 from an adjacent portion of the second grating 104b. Furthermore, the grating structures 102 may have slant angles different that the slant angles of the grating structures 102.

The T1 beams that undergo TIR in the third grating 104c continue to contact gratings of the plurality of grating structures 102 until the either the intensity of the T-1 beams coupled through the optical device 100 to the third grating 104c is depleted, or remaining T1 beams propagating through the third grating 104c have reached the end of the third grating 104c. A portion of the second grating 104b may have grating structures 102 with a slant angle different than the slant angle of grating structures 102 from an adjacent portion of the second grating 104b. Furthermore, the grating structures 102 may have slant angles different that the slant angles of the grating structures 102 and the grating structures 102.

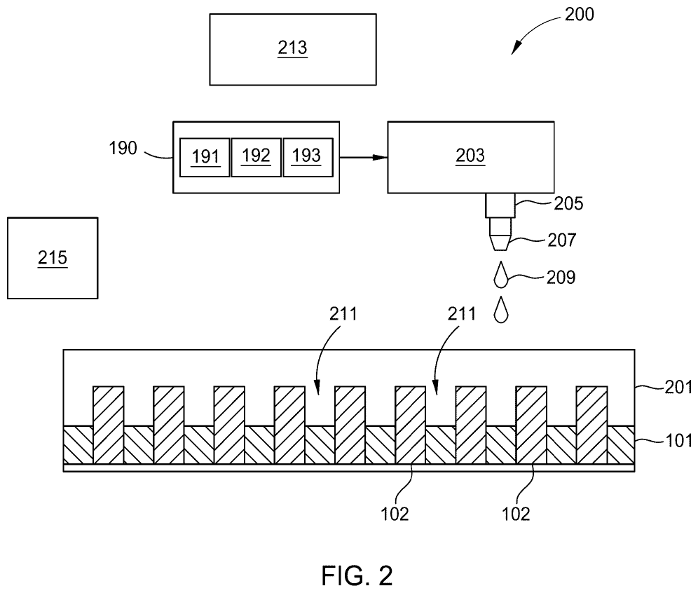

FIG. 2 is a schematic, cross-sectional view of an apparatus 200 for inkjet deposition according to embodiments described herein.

In one embodiment, a film 201 is disposed on the substrate 101 by an inkjet deposition apparatus 200. In some embodiments the film 201 is silicon oxide, but other films are contemplated. The inkjet deposition apparatus 200 includes a jet hub 203, an ultraviolet light source 213, and a fluid supply 215.

The jet hub 203 generally includes a print head 205 and a nozzle 207 for disposing inkjet ink 209 (also referred to as inkjet film). The inkjet ink 209 becomes a film 201 disposed on the optical grating 104. The film 201 is disposed in gaps 211 formed between structures 102 of the grating 104.

The ink 209 may be dispensed at selected locations or regions on the substrate 101. These selected locations collectively form the target printing pattern and can be stored as a CAD-compatible file that is then read by an electronic controller 190 (e.g., a computer) that controls the jet hub 203.

The controller includes a central processing unit (CPU) 193 (e.g., a processor), a memory 191 containing instructions, and support circuits 192 for the CPU 193. The controller 190 controls various items directly, or via other computers and/or controllers. In one embodiment which can be combined with other embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a deposition recipe, and/or a processing recipe) and operations are stored in the memory 191 as a software routine that is executed or invoked to turn the controller 190 into a specific purpose controller to control the operations of the various chambers/modules/apparatus described herein. The controller 190 is configured to conduct any of the operations described herein. The instructions stored on the memory, when executed, cause one or more of the operations (such as the operations of the methods 400, 600, and 800) described herein to be conducted in relation to the processing chamber 300. The controller 190, the apparatus 200, and the processing chamber 300 are at least part of a system for processing substrates.

The ultraviolet light source 213 is directed towards the substrate 101. In some embodiments, the ultraviolet light source 213 is directed towards a patterned substrate 101 and configured to selectively expose and cure all or part of the film 201 disposed on the patterned substrate 101. The controller 190 allows for the directing of UV light from the ultraviolet light source 213. The selective exposure and cure are discussed below.

The fluid supply 215 is configured to supply a fluid to the patterned substrate 101 and the film 201 disposed thereon. In some embodiments, the supplied fluid is a solvent configured to strip a portion of the film 201. The supplied fluid is discussed below.

Inkjet deposition offers a convenient and highly controllable process for producing polishing pads formed from different materials and/or different compositions of materials. For example, inkjet deposition enables efficient and cost-effective incorporation of functional films 201 onto substrates 101, optical devices 100, gratings 104, and structures 102.

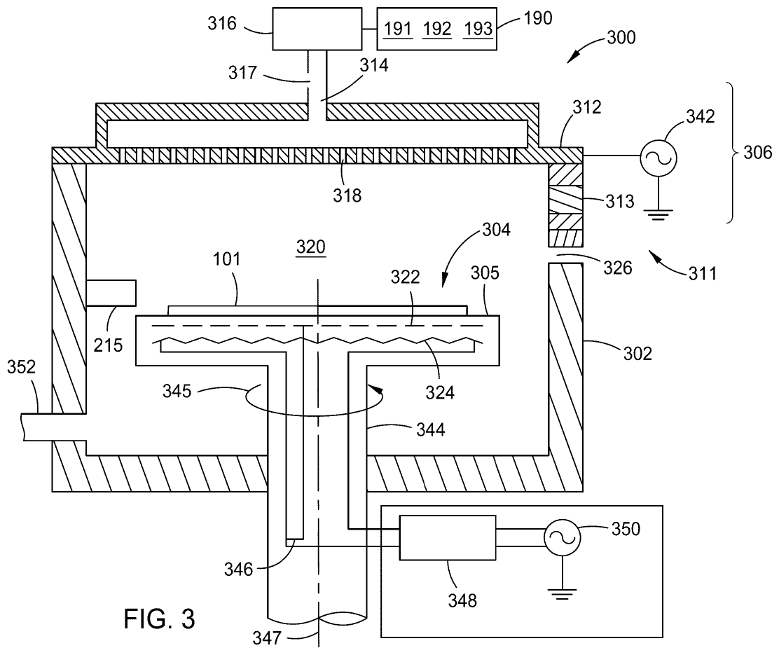

FIG. 3 is a schematic cross-sectional view of an exemplary processing chamber, according to certain embodiments of the present disclosure. FIG. 3 provides an overview of a system that incorporates one or more aspects of the present disclosure and/or which may perform one or more film depositions or other processing operations according to embodiments of the present disclosure. Additional details of chamber 300 or methods performed may be described further below.

The processing chamber 300 may be utilized in certain embodiments of the present disclosure for processing methods that may include formation, film deposition, flowable chemical vapor deposition (flowable CVD) (FCVD) film deposition, photolithography photoresist (PR) deposition, ultraviolet (UV) exposure, photoresist development, film treatment, film etching, or conversion of materials for semiconductor structures. It is to be understood that the chamber described is not to be considered limiting, and any chamber that may be configured to perform operations as described may be similarly used.

Chamber 300 may be utilized to form film layers, e.g., for gap filling, according to certain embodiments of the present disclosure, although it is to be understood that the methods may similarly be performed in any chamber within which film formation may occur. The processing chamber 300 may include a chamber body 302, a substrate support 304 disposed inside the chamber body 302, the ultraviolet light source 213, the fluid supply 215, and a lid assembly 306 coupled with the chamber body 302 and enclosing the substrate support 304 in a processing volume 320. The substrate 101 may be provided to the processing volume 320 through an opening 326, which may be conventionally sealed for processing using a slit valve or door. The substrate 101 may be seated on a surface 305 of the substrate support during processing. The substrate support 304 may be rotatable, as indicated by the arrow 345, along an axis 347, where a shaft 344 of the substrate support 304 may be located. Alternatively, the substrate support 304 may be lifted up to rotate, as necessary, during a deposition process. Additionally, the substrate support 304 includes a cooling device and may be configured to be chilled, e.g., less than or about 300° C., or less than or about 90° C., or less than or about 80° C., or less than or about 70° C., or less than or about 60° C., or less than or about 50° C., or less than or about 40° C., or less than or about 30° C., or less than or about 20° C., or less than or about 10° C., or less.

A flow profile modulator 311 may be disposed in the processing chamber 300 to control flow distribution across the substrate 101 disposed on the substrate support 304. The flow profile modulator 311 may include a first electrode 313 that may be disposed adjacent to the chamber body 302, and may separate the chamber body 302 from other components of the lid assembly 306. The first electrode 313 may be part of the lid assembly 306, or may be a separate sidewall electrode. The first electrode 313 may be an annular or ring-like member, and may be a ring electrode. The first electrode 313 may be a continuous loop around a circumference of the processing chamber 300 surrounding the processing volume 320, or may be discontinuous at selected locations, if desired. The first electrode 313 may also be a perforated electrode, such as a perforated ring or a mesh electrode, or may be a plate electrode, such as, for example, a secondary gas distributor. In some examples, the first electrode 313 may be omitted.

The gas distributor 312 may be coupled with a first source of electric power 342, such as an RF generator, RF power source, DC power source, pulsed DC power source, pulsed RF power source, or any other power source that may be coupled with the processing chamber. In certain embodiments, the first source of electric power 342 may be an RF power source connected to a showerhead 318 of the gas distributor 312.

The gas distributor 312 may be a conductive gas distributor or a non-conductive gas distributor. The gas distributor 312 may also be formed of conductive and non-conductive components. For example, a body of the gas distributor 312 may be conductive while a face plate of the gas distributor 312 may be non-conductive. The gas distributor 312 may be powered, such as by the first source of electric power 342 as shown in FIG. 3, or the gas distributor 312 may be coupled with ground in certain embodiments.

A heater 324, which may be a resistive heater 324, may be coupled with and/or disposed in the substrate support 304. The heater 324 may be coupled with a second source of electric power 350 through a filter 348, which may be an impedance matching circuit. The second source of electric power 350 may be DC power, pulsed DC power, RF bias power, a pulsed RF source or bias power, or a combination of these or other power sources. In certain embodiments, the second source of electric power 350 may be an RF bias power (e.g., configured to provide 2 MHz RF pulsed bias and/or 13.5 MHz RF pulsed bias).

In some embodiments, the second source of electric power 350 may be connected to a chucking electrode 322. The chucking electrode 322 may be disposed within the substrate support 304. In some embodiments, the second source of electric power 350 may be connected to a chucking electrode 322 and the heater 324 by cables 346.

The lid assembly 306 and substrate support 304 of FIG. 3 may be used with any processing chamber for plasma or thermal processing. In operation, the processing chamber 300 may afford real-time control of plasma conditions in the processing volume 320. The substrate 101 may be disposed on the substrate support 304, and process gases may be flowed through the lid assembly 306 using an inlet 314 according to any desired flow plan. Inlet 314 may include delivery from a vapor deposition unit 316, which may be fluidly coupled with the chamber, as well as a bypass 317 for process gas delivery that may not flow through the vapor deposition unit 316 in certain embodiments. Gases may exit the processing chamber 300 through an outlet 352. Electric power may be coupled with the gas distributor 312 to establish a plasma in the processing volume 320.

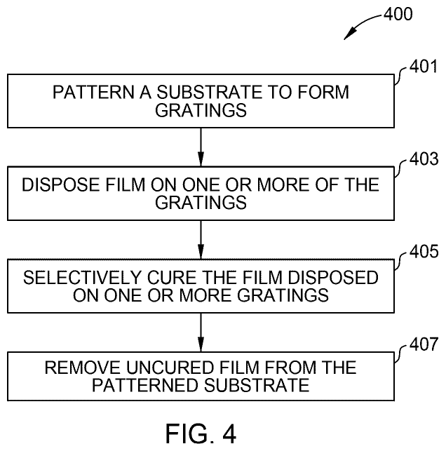

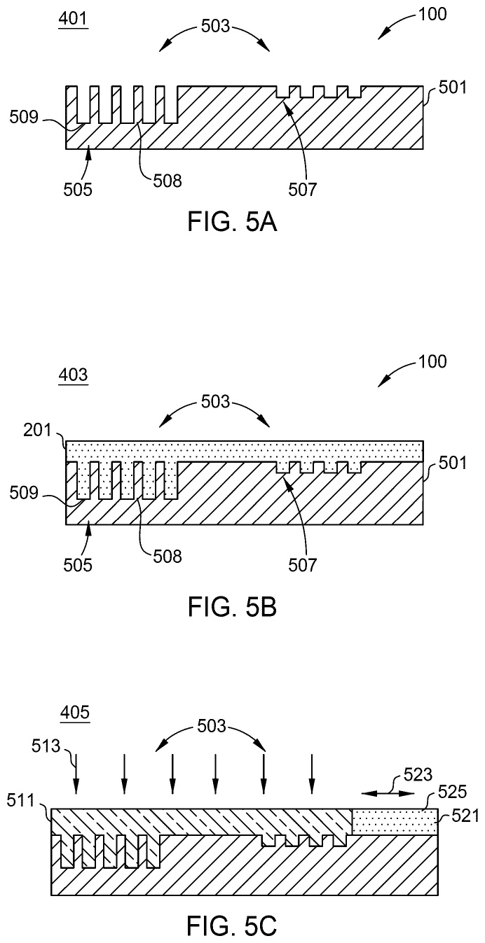

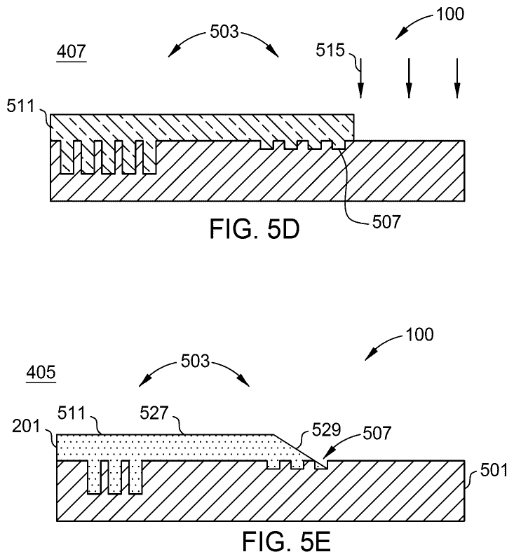

FIG. 4 illustrates a flow diagram of exemplary operations in a film formation method 400, according to certain embodiments of the present disclosure. FIGS. 5A-5E are schematic, cross-sectional views of an optical device during the method 400 of forming a film according to some embodiments.

At operation 401, as shown in FIG. 5A, a substrate is patterned to form a pattered substrate 501. The patterned substrate 501 may include one or more gratings 503 of the optical device 100. In some embodiments, the patterned substrate 501 is the substrate 101 (FIG. 1). In some embodiments, the patterned substrate 501 is a substrate with TiO₂ optical device structures 102 (FIG. 1B) that form the gratings 503. The gratings 503 include an input coupler 505 and the output coupler 507. In some embodiments, which may be combined with other embodiments, the gratings 503 include the first grating 104a corresponding to the input coupling grating, the second grating 104b corresponding to the expanding pupil grating, and the third grating 104c corresponding to the output coupling grating.

At operation 403, as shown in FIG. 5B, a film 201 is disposed on the patterned substrate 501. In some embodiments, which may be combined with other embodiments, the film 201 is disposed over at least the output coupler 507.

In some embodiments, the film 201 is an inkjet film. In some embodiments, the film 201 is disposed by a spin coat process. Inkjet deposition of the film 201 includes photo-curable acrylates, photo-curable epoxy, photo-curable thiol-ene, and any other photo-curable systems. In various embodiments, the ink used to form the film includes monomers, cross-linked polymers, oligomers, polymers, radical photo-initiators, photo-acid generators, photo sensitizers, surfactant, additives, and nanoparticles. For example, the ink may include TiO₂, ZrO₂, HfO, SiO₂, or combinations thereof.

The film 201 has a refractive index between 1 and 2.5. For example, the film 201 has a refractive index between 1.1 and 2.25. The film 201 may also include organic nanoparticles and/or inorganic nanoparticles. For example, the film may include inorganic nanoparticles with a core or shell structure. The composition of the core or shell structure includes silicon oxide (SiO₂), titanium oxide (TiO₂), zirconium oxide (ZrO₂), niobium oxide (Nb₂O₅), hafnium oxide (HfO₂), vanadium oxide (V₂O₅), lead oxide (PbO₂), tantalum oxide (Ta₂O₅), zinc oxide (ZnO), tin oxide (SnO₂), aluminum oxide (Al₂O₃), silver oxide (AgO), silver peroxide (Ag₂O), Li₂O), and any combination thereof.

The fluid, the as deposited film 201, or both may include ligands, for example fatty acid, amines, alcohols, silanes, polyester, polyether, poly (methyl methacrylate) (PMMA), polyvinylalcohol (PVA), polyvinylpyrrolidone (PVP), salts thereof, and any combination thereof. When a ligand is included in the formulation of the fluid used in a spin coat formulation, a fluid in an inkjet ink formulation, or as deposited film, a subsequent cure may optionally remove the ligand.

The film 201 may also include a sol-gel. The sol-gel includes Si cations, Ti cations, Zr cations, Nb cations, Zn cations, Hf cations, Ta cations, and any combination thereof.

The film 201 may also include one or more binders. The binders include epoxy, (meth) acrylate, thiol, vinyl ether, alkene, alkyne, photo-initiator, polymer, and any combination thereof.

The film 201 may also include one or more additives. The additives include, but are not limited to surfactants and rheology modifiers.

The film 201 may also include one or more solvents. The solvents include molecules with a boiling point less than 325° C. For example, the one or more solvents have a boiling point less than 300° C.

The film 201 is disposed over the input coupler 505 and the output coupler 507. The input coupler 505 and the output coupler 507 may be similar to the first grating 104a and second grating 104b of FIG. 1. The input coupler 505 and the output coupler 507 each have structures 508 that define gaps 509 between each structure 508. The film 201 is disposed in the gaps 509 between the structures 508.

In various embodiments, the film 201 is disposed using a bitmap file. The bitmap file includes instructions for depositing the film 201. The bitmap file includes an array of pixels, with each pixel containing data that describes the amount of film to be deposited, for example a deposition rate. The bitmap file allows for enhanced deposition accuracy when higher pixel resolution is utilized. In some embodiments the bitmap is formed by locating first pixels associated with a larger deposition rate on the gratings 503 and second pixels associated with a lower or no deposition rate away from the gratings 503. Pixels located at edges, extensions, or boundaries of the gratings 503 may be third pixels associated with a deposition rate between the deposition rate of the first and second pixels. The third pixels allow for the formation of a gradient deposition of the film 201 on the substrate. The gradient deposition is discussed below.

At operation 405, as shown in FIG. 5C, ultraviolet (UV) light 513 is directed towards the film and the patterned substrate 501. The UV light 513 cures part of the film 201 to form a first portion 511 of the film 201 and a second portion 521 of the film 201. The first portion 511 of the film 201 becomes a cured film, and the second portion 521 of the film 201 becomes an uncured film. The second portion 521 of the film 201 is not exposed to the UV light 513. In various embodiments, when performing inkjet deposition, non-uniformities may exist in an outer region of deposited material. Accordingly, in some embodiments, inkjet deposition is performed beyond the boundary of a particular set of gratings in order to ensure that non-uniformities are not formed over the gratings themselves. For example, the first portion 511 may be positioned over the gratings 503, and the second portion 521 may be positioned outside of (e.g., around a perimeter of) the gratings. The second portion 521 of the film 201 extends a distance 523 outward from the gratings 503. For example, the second portion 521 of the film 201 is an outward extension portion from the nearest gratings 503. The first portion 511 of the film 201 has an approximately uniform thickness. The second portion 521 extends to at least 50 micrometers from the gratings 503. The second portion 521 includes a height 525 from the gratings 503. The height 525 of the second portion 521 is less uniform than the first portion 511. In some embodiments, the second portion 521 of the film 201 has a gradient height (thickness). For example, the second portion (extension portion) 521 of the film 201 may slope from the thickness of the first portion 511, towards the patterned substrate 501. In another example, the second portion 521 of the film 201 may have a thickness greater than the thickness of the first portion 511.

The deposition of the film 201 on the first portion 511 (having the gratings 503) and the second portion 521 enables any non-uniformity arising from the inkjet deposition on the edges to be stripped away, leaving a uniform cured film disposed on one or more of the gratings 503. In some embodiments, the distance 523 that the second portion 521 extends from the nearest one or more gratings 503 is at least 50 micrometers. For example, the film 201 may be disposed on the gratings 503 of the patterned substrate 501 and at least 100 micrometers outward from the gratings 503. In yet another example, the film 201 is disposed on the gratings 503 of the patterned substrate 501 and at least 50 micrometers outward from the gratings 503.

At operation 407, as shown in FIG. 5D one of the first portion 511 of the film 201 or the second portion 521 (FIG. 5C) of the film 201 has been removed by a stripping agent 515. In some embodiments, the second portion 521 is the uncured film and is removed from the patterned substrate 501. In some embodiments, the uncured film (FIG. 5C) is removed with the stripping agent 515 during a strip process. The stripping agent 515 may be a solvent, an etch fluid, an organic solvent, or any combination thereof. For example, the stripping agent 515 may be acetone, acetone solvent, isopropyl alcohol, isopropanol, or another fluid capable of removing an uncured UV ink film without materially damaging the cured film. In some embodiments, which may be combined with other embodiments, the uncured film is removed by an ashing process.

The first portion 511 has a first height from the patterned substrate 501 that is about uniform, and the second portion 521 has a second height greater than the first height.

FIG. 5E represents an alternative embodiment to FIG. 5C. At operation 405, as shown in FIG. 5E, the film 201 is disposed on the patterned substrate 501.

FIG. 5E includes embodiments where the film 201 is deposited as a gradient and operation 407 is not performed. In some embodiments, the whole film 201 can be cured without operation 407. The patterned substrate 501 includes the grating 503 of the optical device 100. In some embodiments, which may be combined with other embodiments, the film 201 includes a first section 527 having an approximately uniform thickness, and a second section 529 having a gradient thickness. For example, the second section 529 may be partially disposed in the grating 503 and slope from a thickness of the first section 527 toward the patterned substrate 501 and into one or more gratings 503. The first portion 511 includes the first section 527 having a uniform thickness and the second section 529 having a gradient thickness formed by the non-uniform deposition of the film 201 at the edges of the deposition and by being partially disposed in the grating 503. For example, the film 201 is partially disposed in the output coupler 507 of the gratings 503, so that the first portion 511 with a gradient thickness in the second section 529 and/or within the output coupler 507 can be achieved. For example, the second section 529 can extend from the height of the first section 527 and slope downward toward the output coupler 507. In another example, the second section 529 may partially fill some structures within the grating 503, but leave other grating structures empty. In another example, the second section 529 may partially fill the grating 503 by uniformly filling all of the grating structures. In another example, the second section 529 may be disposed over the grating 503 in a downward slope from the height of the first section 527 to the surface of the patterned substrate 501. The first portion 511 is then cured to form a first cured section with a uniform thickness from the first section 527 and a second cured section with a gradient thickness from the second section 529.

By using an inkjet deposition to deposit a thin film or gradient film deposition, the grating 503 can be tuned. For example, the optical device 100 may be a waveguide, the grating 503 may be an output coupler 507, and the gradient deposition allows for the waveguide efficiency to be tuned by varying the amount of film deposited on and in the optical device structures of the waveguide.

The amount of amount of film deposited is determined by at least one of the film composition and parameters within the bitmap file. The parameters within the bitmap file include one or more of deposition rate, location of the deposition, time during deposition, but other parameters are contemplated.

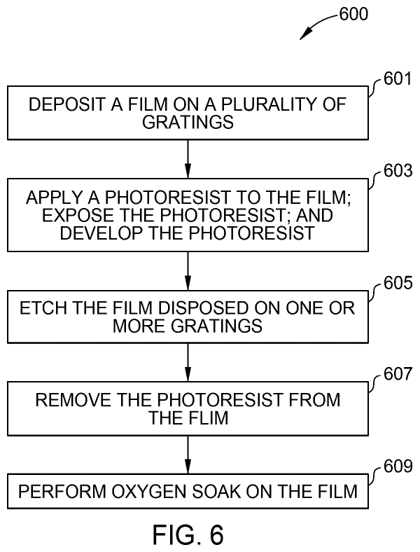

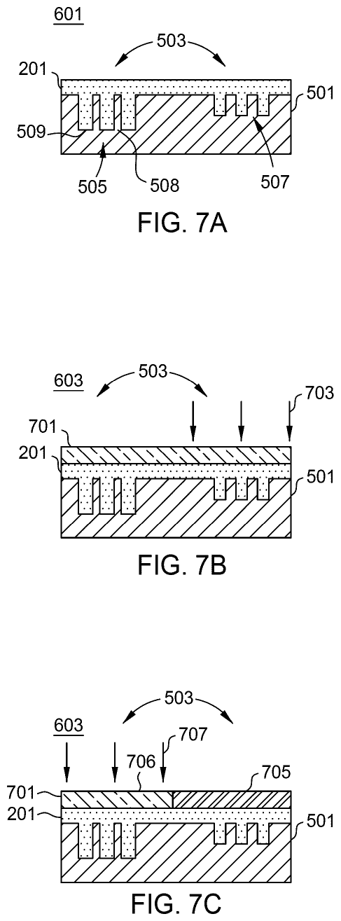

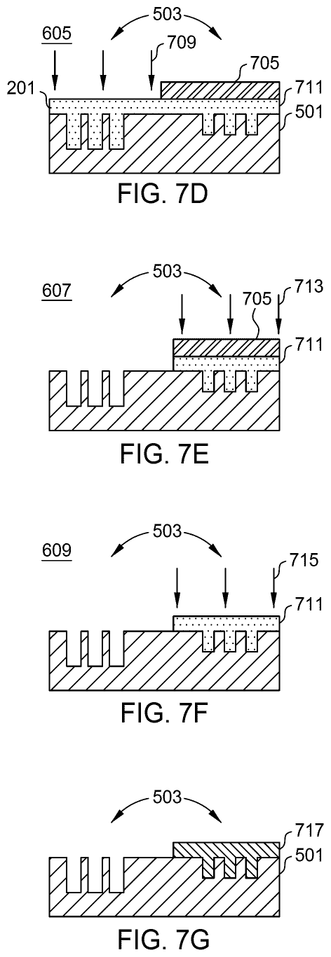

FIG. 6 illustrates a flow diagram of exemplary operations in a film formation method 600, according to certain embodiments of the present disclosure. FIGS. 7A-7G are schematic, cross-sectional views of an optical device during the method 600 of forming a film according to some embodiments.

At operation 601, as shown in FIG. 7A, the film 201 is disposed on the patterned substrate 501. In some embodiments, the film 201 is SiO₂, but other films are contemplated. The patterned substrate 501 includes the gratings 503 of the optical device 100. In some embodiments, the patterned substrate 501 includes a high index substrate having optical structures 102 (FIG. 1B) formed thereon, the structures 102 forming the gratings 503. In some embodiments, the film 201 is disposed on a patterned substrate 501 by a vapor deposition process. For example, the vapor deposition process may be a flowable chemical vapor deposition process (FCVD). In various embodiments, the gases used to form the film 201 include trisilylamine (TSA), ammonia (NH₃), oxygen, argon, helium, or any combination thereof. In some embodiments, the film 201 is a silicon nitride film.

Optionally, method 600 may include forming a patterned substrate 501 by patterning the substrate 101 (FIG. 1B) similar to operation 401 of method 400 prior to depositing the film 201.

At operation 603, as shown in FIGS. 7B and 7C, a photoresist process and photolithography process are performed on the film 201. As shown in FIG. 7B, a photoresist (PR) 701 is disposed on the film 201. The PR 701 is separated from the gratings 503 by the film 201. A light 703 is directed towards the patterned substrate 501. In some embodiments, the light 703 is a UV light that passes through an aligner and that cures a portion of the PR 701. The aligner (not shown) includes a pattern for the film 201 on the optical device.

As shown in FIG. 7C, the PR 701 becomes a cured PR 705 and an uncured PR 706. The light 703 (FIG. 7B) cured a portion of the PR 701 to form the cured PR 705 and the uncured PR 706. In some embodiments, the cured PR 705 is aligned above one or more of the gratings 503. After the light 703 is applied to the PR 701, an etch process (etch operation) is performed on the cured PR 705 and the uncured PR 706. The etch process removes one of the cured PR 705 or the uncured PR 706. The etch process may be a wet etch or a dry etch. The etch process may include an etch fluid 707. The etch fluid 707 is applied to the cured PR 705 and the uncured PR 706 as part of an etch process to remove one of the cured PR 705 or the uncured PR 706. The etch fluid 707 may include tetramethylammonium hydroxide, sodium hydroxide, potassium hydroxide, acetone, propylene glycol methyl ether acetate (PGMEA), but other fluids are contemplated. In some embodiments, a dry etch process removes at least one of the cured PR 705 or the uncured PR 706 by an oxygen plasma. In some embodiments, the etch process removes one of the cured PR 705 or the uncured PR 706. In some embodiments, the etch process removes a portion of the film 201 and one of the cured PR 705 or the uncured PR 706.

At operation 605, as shown in FIG. 7D, the film 201 is etched. The film 201 is etched during a film etch process. A film etch fluid 709 forms a patterned film 711 that is not exposed to the film etch fluid 709. The etch fluid 707 removes the uncured PR 706 (FIG. 7C) leaving the cured PR 705 disposed on the film 201. The cured PR 705 is disposed on and defines the patterned film 711 portion of the film 201. In some embodiments, the film etch process is a wet etch with the film etch fluid 709. The film etch fluid 709 may be sodium hydroxide, or diluted hydrofluoric acid, but other film etch fluids 709 are contemplated. For example, the film etch fluid 709 is diluted hydrofluoric acid between a 750 parts water to 1 part hydrofluoric acid ratio and a 1,250 parts water to 1 part hydrofluoric acid ratio. In some embodiments, film etch process is a dry etch and the film etch fluid 709 is carbon tetrafluoride. Operations 603 and 605 are examples of a block lithography process.

At operation 607, as shown in FIG. 7E, a PR removal process is applied. The PR removal process removes the cured PR 705 with a PR etch fluid 713, after a patterned film 711 has been formed. The film etch process of operation 605 has formed a patterned film 711 from the film 201. In various embodiments, the film etch fluid 709 removed the portions of the film 201 (FIG. 7D) not disposed between the cured PR 705 and patterned substrate 501. The patterned film 711 is disposed between the patterned substrate 501 and the cured PR 705. For example, the patterned film 711 is disposed between one or more gratings 503 of the patterned substrate 501 and the cured PR 705. The PR removal process may be an ash, a wet etch, or a dry etch. For example, the PR etch may be a wet etch and include applying the PR etch fluid 713. The PR etch fluid 713 may be propylene glycol monomethyl ether acetate, diluted hydrofluoric acid, or acetone, but other fluids are contemplated. In another example, the PR etch fluid 713 may be diluted hydrofluoric acid between a 750 parts water to 1 part hydrofluoric acid ratio and a 1,250 parts water to 1 part hydrofluoric acid ratio.

In some embodiments, operation 605 is optional. For example, in some embodiments, the etch fluid 707 (FIG. 7C) may etch one of the cured PR 705 or the uncured PR 706 in addition to a portion of the film 201 disposed below the cured PR 705 or the uncured PR 706, in order to form the patterned film 711. Accordingly, in such embodiments, operation 605 may be omitted.

At operation 609, as shown in FIGS. 7F and 7G, a curing agent 715 is applied to the patterned film 711. In various embodiments, the curing agent 715 is an oxygen soak. After the PR etch fluid 713 has removed the cured PR 705 (FIG. 7E) the patterned film 711 remains on the patterned substrate 501. After the cured PR 705 has been removed, the curing agent 715 is applied to the patterned film 711. The curing agent 715 may include applying ozone to the patterned film 711 to form a cured film 717. In some embodiments, oxygen soak is performed at about 400 torr to about 600 torr. In some embodiments, the curing agent 715 is UV light. For example, when the film 201 is a silicon nitride film, UV light may be used instead of or in addition to oxygen to cure the film.

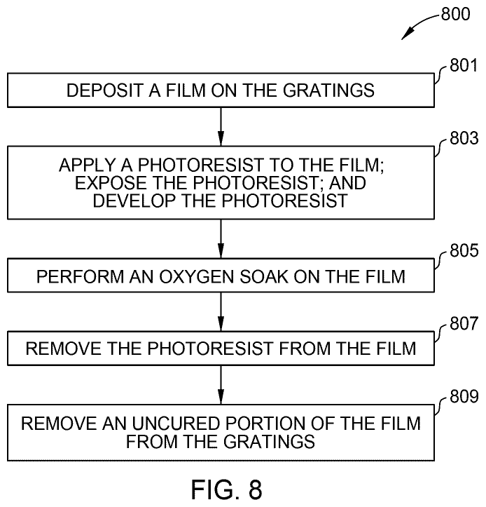

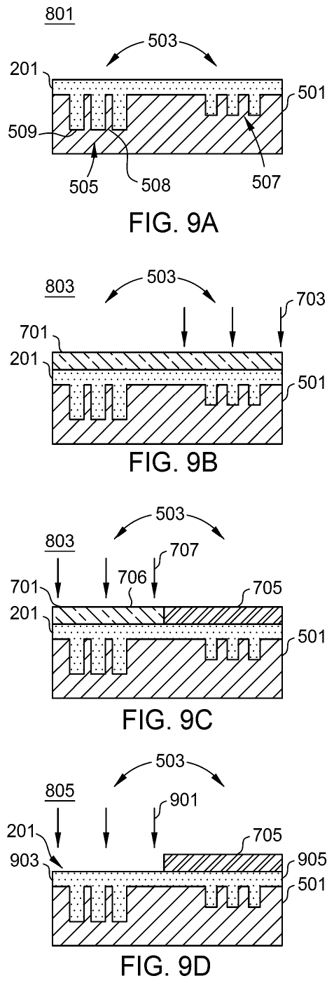

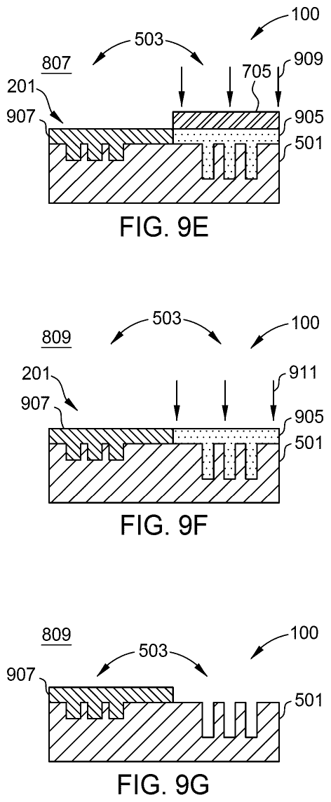

FIG. 8 illustrates a flow diagram of exemplary operations in a film formation method 800, according to certain embodiments of the present disclosure. FIGS. 9A-9G are schematic, cross-sectional views of an optical device during the method 800 of forming a film according to some embodiments.

Optionally, method 800 may include forming the patterned substrate 501 by patterning the substrate 101 (FIG. 1B) similar to operation 401 of method 400 prior to depositing the film 201.

The method 800 is similar to the method 600. At operation 801, as shown in FIG. 9A, the film 201 is disposed on the patterned substrate 501. The patterned substrate 501 includes the gratings 503 of the optical device 100. In some embodiments, the film 201 is disposed on a patterned substrate 501 by a vapor deposition process.

At operation 803, as shown in FIGS. 9B and 9C, a photoresist process and photolithography process are performed on the film 201. As shown in FIG. 9B, the PR 701 is disposed on the film 201 and exposed to light 703. The light 703 is directed towards the patterned substrate 501. In some embodiments, the light 703 is UV light that cures a portion of the PR 701.

As shown in FIG. 9C, the etch fluid 707 is applied to the cured PR 705 and the uncured PR 706 of the film 201 as part of an etch process. As shown, the light 703 (FIG. 9B) has cured a portion of the PR 701 to form the cured PR 705 and the uncured PR 706. The PR 701 includes the cured PR 705 and the uncured PR 706. In some embodiments, the cured PR 705 is aligned above one or more of the gratings 503. The etch fluid 707 is applied to remove at least one of the cured PR 705 or the uncured PR 706. The etch process may be a wet etch or a dry etch.

In contrast to the method 600, at operation 805, as shown in FIG. 9D, an oxygen soak 901 is applied to an exposed portion 903 of the film 201. The oxygen soak 901 is applied after the etch fluid 707 removes the uncured PR 706 (FIG. 9C) but before the cured PR 705 is removed. After the uncured PR 706 (FIG. 9C) has been removed, the cured PR 705 is disposed over and defines an unexposed portion 905 of the film 201. The unexposed portion 905 of the film 201 is disposed between the uncured PR 706 and one or more of the gratings 503 of the patterned substrate 501. The oxygen soak 901 may include applying ozone to the exposed portion 903 of the film 201.

At operation 807, as shown in FIG. 9E, an etch fluid 909 is applied to the patterned substrate 501 as part of an etch operation. Operation 807 is similar to operation 607 (FIG. 7E) described above. As shown, the oxygen soak 901 has formed a cured portion 907 of the film 201 from the exposed portion 903 (FIG. 9D) of the film 201. As described above, the oxygen soak 901 reacts with the exposed portion 903 of the film 201, but not the unexposed portion 905. The etch fluid 909 is applied to remove the cured PR 705. The etch operation may be a wet etch or a dry etch. The etch fluid 909 is applied to remove the cured PR 705 from the patterned substrate 501 and the unexposed portion 905 of the film 201.

At operation 809, as shown in FIG. 9F, a film etch fluid 911 is applied to the optical device 100. The film etch fluid 911 is similar to the film etch fluid 709 (FIG. 7D) described above. After the etch fluid 909 (FIG. 9E) has removed the cured PR 705, the film etch fluid 911 removes the unexposed portion 905 of the film 201 from the patterned substrate 501.

After the unexposed portion 905 of the film 201 has been removed, as shown in FIG. 9G, the cured portion 907 of the film 201 forms a patterned film disposed over and in one or more of the gratings 503 of the patterned substrate 501 of optical device 100.

Benefits of the present disclosure include, but are not limited to, reduction in steps in inkjet and/or FCVD formation of cured films. For example, the above allows for higher throughput when manufacturing optical devices. The above described methods allow for an inkjet deposition with fewer steps when compared to a process that utilizes a photoresist. Further, the above described methods allow for FCVD deposition with fewer steps when compared to a process that utilizes a photoresist on a cured film that has not been patterned.

What is claimed is:

1. A method of forming a film on an optical device, the method comprising:
disposing a film on a patterned substrate, the patterned substrate comprising:
a first grating; and
a second grating, the first grating and second grating formed from optical device structures, the film disposed on at least one of the first grating or second grating;
directing ultraviolet (UV) light toward at least one of first grating or the second grating of the patterned substrate to form a first portion of the film and a second portion of the film; and
removing one of the first portion of the film or the second portion of the film.

2. The method of claim 1, wherein
the disposing the film comprises performing inkjet deposition on the patterned substrate,
the directing the UV light cures the first portion of the film to form a cured film and the second portion of the film comprising an uncured film, and
the removing comprises removing the uncured film, wherein the second portion of the film is not exposed to the UV light.

3. The method of claim 2, wherein the inkjet deposition comprises depositing the film on an optical device of the patterned substrate, and the uncured film is disposed outward of the cured film to form an extension portion on the patterned substrate that extends at least 50 micrometers from the optical device, and the removing is a strip process that removes the extension portion.

4. The method of claim 2, wherein the removing the uncured film comprises applying an organic solvent.

5. The method of claim 1, further comprising:
disposing a photoresist on the film;
after directing the UV light, removing the photoresist, wherein the removing one of the first portion of the film or the second portion of the film comprises removing the first portion by applying an acetone solvent, a wet etch, a dry etch, or an ashing process; and
curing the first portion of the film or the second portion of the film with oxygen,
wherein the disposing the film comprises performing a flowable CVD deposition.

6. The method of claim 5, wherein removing the photoresist comprises one of applying a solvent or performing an ashing process.

7. The method of claim 5, wherein the first portion of the film is disposed on an input coupler of the patterned substrate, and the second portion of the film is disposed on an output coupler of the patterned substrate, the photoresist disposed on the second portion of the film.

8. A method of forming a film on an optical device, the method comprising:
disposing a film on a patterned substrate by one of deposition or spin coating; and
curing the film with ultraviolet (UV) light to form a cured film, wherein at least part of the film is disposed over an output coupler of the optical device.

9. The method of claim 8, wherein the film comprises a first portion and a second portion extending outward from the first portion, the first portion having a first height from the patterned substrate, wherein the first height is approximately uniform, and the second portion has a second height greater than the first height.

10. The method of claim 8, wherein the cured film comprises a cured section having a gradient thickness.

11. The method of claim 8, wherein curing the film comprises curing a first portion of the film to form a cured film from the first portion of the film and an uncured film from a second portion of the film, and the method further comprises removing the uncured film.

12. The method of claim 11, wherein removing the uncured film comprises applying an organic solvent to the film.

13. The method of claim 11, wherein the first portion of the film is disposed over the output coupler, and the second portion of the film extends out from the first portion of the film at least 100 micrometers or more.

14. The method of claim 11, wherein the UV light passes through an aligner before curing the first portion of the film.

15. A method of forming a film on an optical device, the method comprising:
disposing a film on a patterned substrate by a chemical vapor deposition (CVD);
disposing a photoresist on the film;
curing a portion of the photoresist disposed on the film to form a cured portion of the photoresist and an uncured portion of the photoresist;
performing one or more etch operations; and
applying oxygen to the film.

16. The method of claim 15, wherein performing one or more etch operations comprises:
etching the photoresist with a first etch operation; and
forming a patterned film from the film with a second etch operation.

17. The method of claim 16, wherein the second etch operation is a wet etch.

18. The method of claim 16, wherein the second etch operation is a dry etch.

19. The method of claim 15, wherein performing one or more etch operations comprises etching the photoresist and the film with tetramethylammonium hydroxide.

20. The method of claim 15, further comprising removing the photoresist before applying oxygen to the film.
